(19) United States
(12) Patent Application Publication
(10) Pub. No.: US 2008/0100330 A1
(43) Pub. Date: May 1, 2008

(54) TEST APPARATUS, PERFORMANCE BOARD AND INTERFACE PLATE

(75) Inventors: Yoshimasa Ito, Tokyo (JP); Shozo Hayashi, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/945,993

(22) Filed: Nov. 27, 2007

Related U.S. Application Data
(63) Continuation of application No. PCT/JP2006/315239, filed on Aug. 1, 2006.

(30) Foreign Application Priority Data
Aug. 5, 2005 (JP) 2005-228289

(51) Int. Cl. G01R 31/26

(52) U.S. Cl. 324/765

(57) ABSTRACT

A semiconductor testing device 20 is provided that can connect en bloc a variety of connectors of a performance board 200. The semiconductor testing device 20 includes a test head main body 100 that includes a signal module 110 that generates and processes test signals input and output to a device under test 10, an interface plate 200 that is attached to the test head main body 100 and includes a plurality of receptacles electrically connected to a plate body 210 and the signal module 110 and disposed on the plate body 210, and a performance board 300 that includes on one surface connectors fit into and electrically connected to the receptacles and on another surface a test socket 330 that is electrically connected to the connectors and on which the device under test 10 can be mounted and is attached to the interface plate 200 by fitting the connectors into the receptacles. In the semiconductor testing device 20, the plurality of receptacles or the plurality of connectors include rise/fall receptacles or rise/fall connectors that are displaced in relation to the plate body 210 in a direction in which the connectors are inserted into or removed from the receptacles.

### CROSS REFERENCE TO RELATED APPLICATION

This is a continuation application of PCT/JP2006/315239 filed on Aug. 1, 2006 which claims priority from a Japanese Patent Application(s) NO. 2005-228289 filed on Aug. 5, 2005, the contents of which are incorporated herein by reference.

### BACKGROUND

1. Technical Field

The present invention relates to a semiconductor testing device a performance board, and an interface plate. More particularly, the present invention relates to a semiconductor testing device that performs testing of a device under test by inputting and outputting a test signal between the device under test and an interface plate provided with the semiconductor testing device.

2. Background Art

In general, the quality of semiconductor devices is controlled by testing during manufacturing and before shipping. Such testing is performed by temporarily attaching a device under test to a semiconductor testing device and inputting and outputting a test signal between the device under test and a signal module attached to the semiconductor testing device.

However, various types of semiconductor devices such as so-called SoCs (System on Chip), SIPs (System in Package), system LSIs, and the like have been developed in recent years. Such types of semiconductor devices are circuits having different functions, such as a processor, a memory, an input/output circuit, and a control circuit, gathered into a single chip or package. Such types of semiconductors have greatly contributed to miniaturizing and lowering power consumption of electronic products by greatly decreasing surface area for implementation, decreasing power consumption, decreasing the cost of implementation, and the like.

Because circuits handling different types of signals are housed together, such types of semiconductor devices necessitate a wide range of various types of test signals to input and output during testing of the semiconductor. For example, electric signals require different signal transmission paths having appropriate specifications according to the bandwidth, strength, and the like of the signals. Because of this, handling of the test signals in the semiconductor testing device also becomes complicated.

Japanese Patent Application Publication No. 2004-108898 describes a test system that can perform an SoC test and a performance board used therein. The performance board is provided with a test head that can be attached directly to the device under test. Furthermore, the performance board is provided with a connector to provide an electrical connection to the test apparatus. In addition, the test head and connector are electrically connected on the performance board. Accordingly, by attaching the performance board provided with the appropriate test head to the test apparatus, devices under test having different physical connection structures can be easily mounted on the test apparatus.

In addition, an adapter including different types of connectors is mounted on the aforementioned performance board, so that signals having different bandwidths or strengths can be handled simultaneously. Accordingly, even an SoC on which, for example, a circuit that handles RF (Radio Frequency) signals is mounted can simultaneously test a logic circuit and the RF signal circuit. In addition, by replacing the performance board, testing of other devices under test having different specifications can be easily performed.

There are cases where the device under test is commonly known as a DUT (Device Under Test). There are also cases where the semiconductor testing device is called an automatic test apparatus or an ATE (Automatic Test Equipment). Furthermore, the performance board can also be called a load board, a circuit board, or the like. In addition, there are cases where the interface plate is called a HIFIX, a test head chassis, a test fixture, a top plate, or the like.

Devices under test such as SoCs, SIPs, and system LSIs have an extremely high number of input/output terminals. Furthermore, as described above, the signals being handled include various bandwidths and strengths. Because of this, many varieties are also included in a signal medium and a connection structure for connecting the performance board and the test apparatus. Accordingly, connecting the performance board and the test apparatus is not a simple procedure, thereby resulting in a decrease in efficiency of the overall testing procedure because of the replacement of the performance board. In response to this, intervening a member called an interface plate between the performance board and the test apparatus to simplify the procedure of attaching the performance board has been proposed.

The interface plate is attached to a test apparatus side and is provided with receptacles connected to the input/output terminals of the test signal in the test apparatus. Furthermore, the receptacles correspond to connectors attached to a performance board side. Accordingly, the performance board can quickly be mounted on the test apparatus to which the interface plate is attached in advance by fitting the connectors into the receptacles. Furthermore, by setting the connectors on the performance board side to be physically disposed corresponding to the receptacles on the interface plate side, the plurality of connectors can be simultaneously fit into the plurality of receptacles en bloc. In the following description, a connection structure of one group of a connector and a receptacle is referred to as a “connector pair”.

However, there are cases where members having different fitting strokes are included in the connector pairs. Furthermore, there is a problem that a great deal of force is necessary to simultaneously join the connector pairs en bloc.

### SUMMARY

Therefore, it is an object of an aspect of the present invention to provide a test apparatus and an interface plate, which are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary apparatus may include a semiconductor testing device. The semiconductor testing device includes a test head that includes a signal module that generates and processes test signals input to and then output from a device under test, an interface plate that is attached to the test head and includes a plate body and a plurality of receptacles electrically connected to the signal module and disposed on the plate body, and a performance board that includes on one surface connectors fit into and electrically joined with the receptacles and on another surface a test socket that is electrically connected to the connectors and on which the device under test can be mounted and is attached to the interface plate by fitting the connectors into the receptacles. In the semiconductor testing device, the plurality of receptacles or the plurality of connectors include rise/fall receptacles or rise/fall connectors that are displaced in relation to the plate body in a direction in which the connectors are inserted into or removed from the receptacles. Therefore, even where connector pairs having different fitting strokes are mixed in with the connection of the interface plate and the performance board, the connector pairs can be connected en bloc. Accordingly, a procedure of attaching or replacing the performance board can be completed quickly.

As another embodiment, in the semiconductor testing device described above, the plurality of connectors and receptacles is disposed in a circle that surrounds the device under test attached to the test socket. Therefore, on the performance board, distances between the device under test and each connector can be caused to be uniform, thereby avoiding degradation of test precision caused by differences in lengths of the signal transmission paths.

As another embodiment, in the semiconductor testing device described above, the plurality of connectors and receptacles is disposed in a plurality of circles, each circle having a common center, that surrounds the device under test attached to the test socket. Therefore, density of the mounted connectors and the receptacles can be increased to correspond to a device under test having an extremely high number of terminals.

As another embodiment, in the semiconductor testing device described above, the rise/fall receptacles or the rise/fall connectors are elastically supported from the plate body and are displaced together with the inserted connectors in a direction in which the connectors are inserted or removed. Therefore, after the connectors are fully fit into the receptacles in the connector pairs having short fitting strokes, the receptacles are displaced together with the connectors. Accordingly, even in connector pairs having long fitting strokes, the connectors can be fully fit into the receptacles.

As another embodiment, in the semiconductor testing device described above, the receptacles are supported by the plate body via receptacle holders that have a portion with a shape complementing the receptacles and hold a plurality of the receptacles. Therefore, replacement of the receptacles becomes easy and interface plates having different specifications can be easily and quickly installed.

As another embodiment, in the semiconductor testing device described above, the receptacle holders include a rise/fall receptacle holder that holds the rise/fall receptacles, and the rise/fall receptacle holder displaces in relation to the plate body in a direction in which the connectors are inserted into or removed from the receptacles by displacing in relation to the plate body in a direction in which the connectors are inserted into or removed from the receptacles. Therefore, a plurality of rise/fall receptacles stored in a single rise/fall receptacle holder can be raised or lowered en bloc by a single raising/lowering mechanism. Accordingly, the structure of the interface plate can be simplified.

As another embodiment, in the semiconductor testing device described above, the receptacle holders are disposed in a circle that surrounds the device under test attached to the test socket. Therefore, the connectors corresponding to the receptacles can be disposed on the performance board at uniform distances in relation to the test socket. Accordingly, the lengths between the connectors and the device under test can be caused to be uniform, thereby realizing highly accurate testing.

As another embodiment, in the semiconductor testing device described above, the receptacle holders are disposed in a plurality of circles, each circle having a common center, that surrounds the device under test attached to the test socket. Therefore, density of the mounted receptacles on the interface plate can be increased, as can the density of the mounted connectors on the performance board. Accordingly, correspondence with a device under test having an extremely high number of terminals can be achieved.

As another embodiment, in the semiconductor testing device described above, each receptacle holder holds receptacles having fitting strokes equal to one another. Therefore, a single receptacle holder can handle a plurality of receptacles en bloc.

As another embodiment, the semiconductor testing device described above further includes a guiding section that guides the displacement of the rise/fall receptacle holder in a direction in which the connectors are inserted into or removed from the receptacles, a slanted surface formed on the rise/fall receptacle holder that slants in relation to a front surface of the plate body, and a driving section that displaces the rise/fall receptacle holder by contacting the slanted surface and displacing the rise/fall receptacle holder horizontally. Therefore, the rise/fall receptacles can be displaced by a process of attaching the performance board because the rise/fall receptacles can be indirectly displaced. Furthermore, raising and lowering of the receptacles can be performed from outside the interface plate. In addition, raising and lowering of the receptacles can be motorized.

As another embodiment, in the semiconductor testing device described above, the fitting strokes of the rise/fall receptacles and the corresponding connectors are longer than the fitting strokes of other receptacles and corresponding connectors and, during a procedure in which the connectors are fit into the receptacles, the rise/fall receptacles are displaced toward the connectors after the other connectors are fit into the other receptacles. Therefore, even in a case where connector pairs having long fitting strokes are mixed in, the connector pairs having the long fitting strokes can be reliably connected.

As another embodiment, the fitting strokes of the rise/fall receptacles and the corresponding connectors are shorter than the fitting strokes of other receptacles and corresponding connectors and, during a procedure in which the connectors are fit into the receptacles, the rise/fall receptacles and the connectors are displaced until the other connectors are fit into the other receptacles after the connectors are fit into the rise/fall receptacles. Therefore, connector pairs having different fitting strokes can be reliably connected without performance of a special operation.

As another embodiment, in the semiconductor testing device described above, the receptacles are multi-receptacles that have a plurality of terminals causing electrical coupling independent of one another. Therefore, the density of the mounted receptacles and connectors can be further increased.

As another embodiment, in the semiconductor testing device described above, the receptacles are coaxial receptacles that have a core line and a conductive shield surrounding the core line. Therefore, testing can be performed using test signals having high bandwidths that require use of a signal transmission path that includes specialized impedance or test signals that affect one another through interference or unnecessary radiation.

According to a second aspect related to the innovations herein, one exemplary apparatus may include an interface plate, on which is loaded a performance board that is provided with a plate body attached to a test head of a semiconductor testing device and a plurality of receptacles disposed on the plate body and electrically connected to a signal module that generates test signals for testing the device under test and includes on one surface thereof connectors that are fit into and electrically connected to the receptacles. In the interface plate, the plurality of receptacles includes rise/fall receptacles that are displaced in relation to the plate body in a direction in which the connectors are inserted into or removed from the receptacles. Therefore, connector pairs having different fitting strokes can be mixed in and the interface plate and the performance board can be connected en bloc.

According to a third aspect related to the innovations herein, one exemplary apparatus may include a performance board that includes a test socket on which a device under test can be mounted on a test head of a semiconductor testing device, a board main body on which the test socket is loaded on one surface thereof, and a plurality of connectors attached to another surface of the board main body that fits into receptacles that are electrically connected to a signal module that generates test signals for testing the device under test. In the performance board, the plurality of connectors includes rise/fall connectors that are displaced in relation to the board main body in a direction in which the connectors are inserted into or removed from the receptacles. Therefore, connector pairs having different fitting strokes can be mixed in and the performance board can be connected en bloc.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a cross-sectional view of a portion of a semiconductor testing device 20 according to the present embodiment.

FIG. 2 is a magnified view of an area surrounded by the dotted lines shown in FIG. 1.

FIG. 3 is a perspective view of a performance board 300.

FIG. 4 is a vertical sectional view of the performance board 300.

FIG. 5 shows a process of attaching the performance board 300 in one embodiment.

FIG. 6 shows a process of attaching the performance board 300 in the aforementioned embodiment.

FIG. 7 shows a process of attaching the performance board 300 in the aforementioned embodiment.

FIG. 8 shows a modification of the aforementioned embodiment.

FIG. 9 shows a process of attaching the performance board 300 in another embodiment.

FIG. 10 shows a process of attaching the performance board 300 in the aforementioned embodiment.

FIG. 11 shows a process of attaching the performance board 300 in the aforementioned embodiment.

FIG. 12 is an exploded perspective view showing a structure of attached receptacles on the interface plate 200.

FIG. 13 is a plan view showing a single driving section 400 that raises and lowers rise/fall receptacle holder 260.

FIG. 14 is a side view of members shown in FIG. 13.

FIG. 15 is a cross-sectional view showing a portion of the members shown in FIG. 13.

FIG. 16 is a partial plan view showing the interface plate 200 having each member attached.

### DESCRIPTION OF EXEMPLARY EMBODIMENTS

Hereinafter, aspects of the present invention will be described through embodiments. The embodiments do not limit the invention according to the claims, and all the combinations of the features described in the embodiment are not necessarily essential to means provided by aspects of the invention.

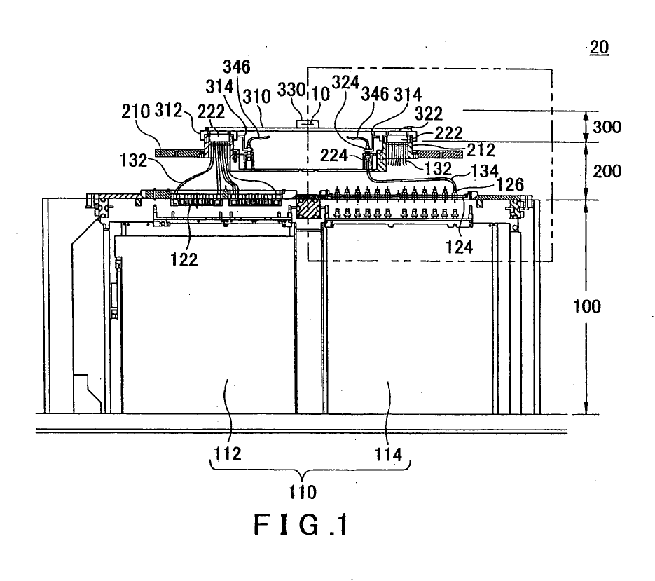

FIG. 1 is a cross-sectional view of a portion of a semiconductor testing device 20 according to the present embodiment. As shown in FIG. 1, the semiconductor testing device 20 includes a performance board 300 and an interface plate 200 layered sequentially on a test head main body 100.

The present embodiment describes a case where test signals having different frequencies and powers are used in a connection terminal of a single device under test 10. In other words, a case where, for example, a test that uses a test signal having an RF (Radio Frequency) bandwidth is performed at the same time as a test that uses a common analog or digital test signal (A/D test signal). In such a case, a connector, a receptacle, and a cable, which are compatible with the power or frequency used by the test signals, are used for the electrical connection between the device under test 10 and the test head main body 100. The following embodiment describes a case where a logic signal and an RF signal are used simultaneously as the test signals.

The test head main body 100 generates the test signals input and output to the device under test 10, processes the test signals sent back from the device under test 10, and evaluates the device under test 10. In the present embodiment, the test head main body 100 is provided with a signal module 110 that includes a logic signal module 112 that generates and processes a logic test signal and an RF signal module 114 that generates and processes an RF test signal.

The logic test signal generated by the logic signal module 112 is input and output via a logic signal terminal board 122 attached to a top surface of the logic signal module 112. The RF test signal generated by the RF signal module 114 is input and output via a coaxial terminal board 124 attached to the top surface of the RF signal module 114.

The interface plate 200 is provided with a circular plate body 210, a plurality of logic signal receptacles 222 attached to the plate body 210, and a plurality of RF signal receptacles 224 also attached to the plate body 210. The logic signal receptacles 222 are connected to the logic signal module 112 via a logic signal connection cable 132 and the logic signal terminal board 122. The RF signal receptacles 224 are connected to the RF signal module 114 via a coaxial cable 134 and the coaxial terminal board 124.

Each logic signal receptacle 222 contains a plurality of connector pins and each connector pin is independently connected to the logic signal module 112. Accordingly, the logic signal receptacles 222 are multi-receptacles that can simultaneously connect a plurality of logic signals. On the other hand, the RF signal receptacles 224 are so-called coaxial receptacles that include a core line and a conductive shield surrounding the core line.

The performance board 300 is provided with a circular board main body 310 and a test socket 330 loaded substantially centrally on a top surface of the board main body 310. The test socket 330 is provided with a connector pin corresponding to the connection terminal of the device under test 10, so that the device under test 10 can be easily mounted.

Furthermore, an outer member 312 that reinforces the mechanical strength of the board main body 310 is attached to a border portion of a bottom surface of the board main body 310. A logic signal connector 322 is attached to a bottom surface of the outer member 312. An RF signal connector 324 supported by the outer member 312 via a bracket 314 is attached to an inner side of the logic signal connector 322.

To describe the drawings concisely, both a pair of logic signal modules 112 and a pair of RF signal modules 114 are drawn in FIG. 1. However, a multitude of signal modules 110 is actually attached. Furthermore, a multitude of logic signal connection cables 132 and a multitude of coaxial cables 134 are attached corresponding to the multitude of signal modules 110.

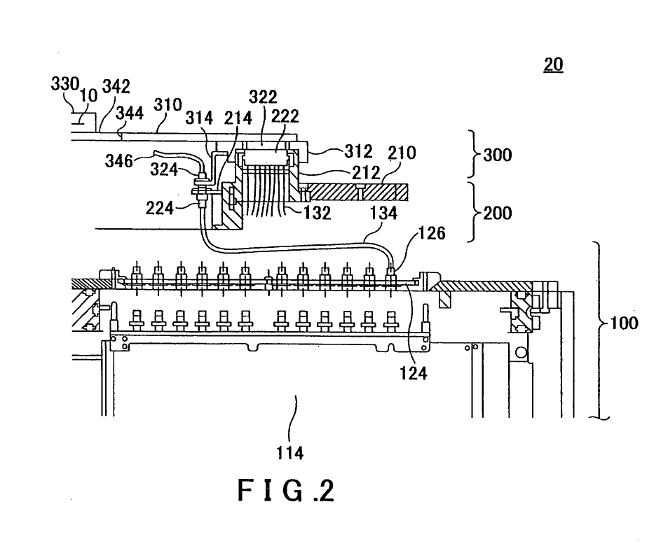

FIG. 2 shows a magnified view of an area surrounded by the dotted lines shown in FIG. 1. In FIG. 2, the same reference numbers are given to structural elements common to FIG. 1 and overlapping descriptions are omitted.

As shown in FIG. 2, the logic signal connector 322 attached to the bottom surface of the performance board 300 is paired with the logic signal receptacle 222 on the interface plate 200 side to form a logic signal connector pair. In the same manner, the RF signal connector 324 is paired with the RF signal receptacle 224 to form an RF signal connector pair.

On the other hand, the RF signal receptacle 224 of the interface plate 200 is connected to the RF signal module 114 via the coaxial cable 134, the RF signal connector 126, and the coaxial terminal board 124. Furthermore, though not shown in FIG. 2, the logic signal receptacle 222 is connected to the logic signal module 112 as described above. Accordingly, each connection terminal of the RF signal receptacle 224 and the logic signal receptacle 222 of the interface plate 200 can be seen as being electrically equivalent to the input/output terminal of the signal module 110.

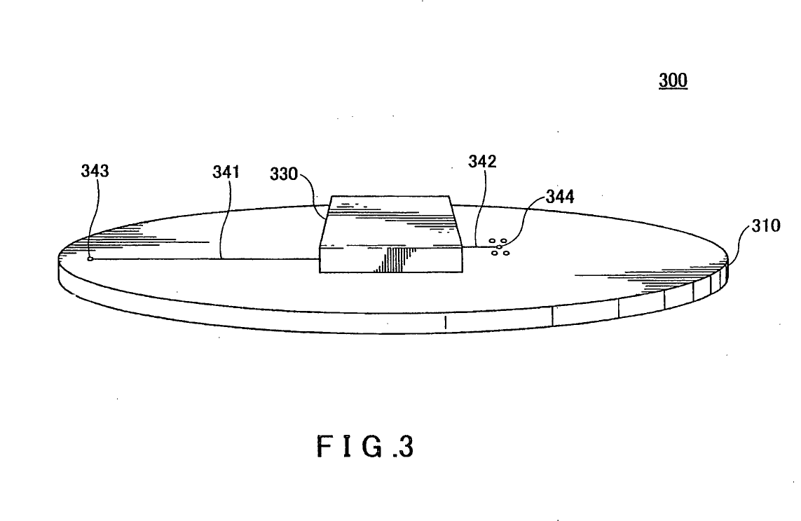

FIG. 3 is a perspective view of the performance board 300 in the semiconductor testing device 20 shown in FIGS. 1 to 3. As shown in FIG. 3, the test socket 330 is mounted in a substantial center of the substantially circular board main body 310. The board main body 310 can be formed using materials for an electrical circuit board, for example. A paper phenol substrate, a paper epoxy substrate, a glass epoxy substrate, a fluorine resin substrate, and the like are known as materials for an electrical circuit board, and any material having constant bending rigidity and insulation can be desirably applied. Furthermore, the performance board 300 is provided with a single test socket 330, but a plurality of test sockets 330 may also be provided.

Signal lines 341, 342, serving as paths for the test signals, extend radially from the test socket 330 as a center on the top surface of the board main body 310. Furthermore, vias 343, 344 penetrating through the board main body 310 are formed in a periphery of the test socket 330. The signal lines 341, 342 are electrically connected to the bottom surface of the board main body 310 via the vias 343, 344. The signal lines 341, 342 may be microstrip lines formed on the board main body 310.

To present the diagram of FIG. 3 concisely, one of each of the signal lines 341, 342 is drawn. However, the signal lines are increased according to a number of connection terminals of the device under test 10. Accordingly, a multitude of signal lines, from tens to hundreds thereof, is actually formed.

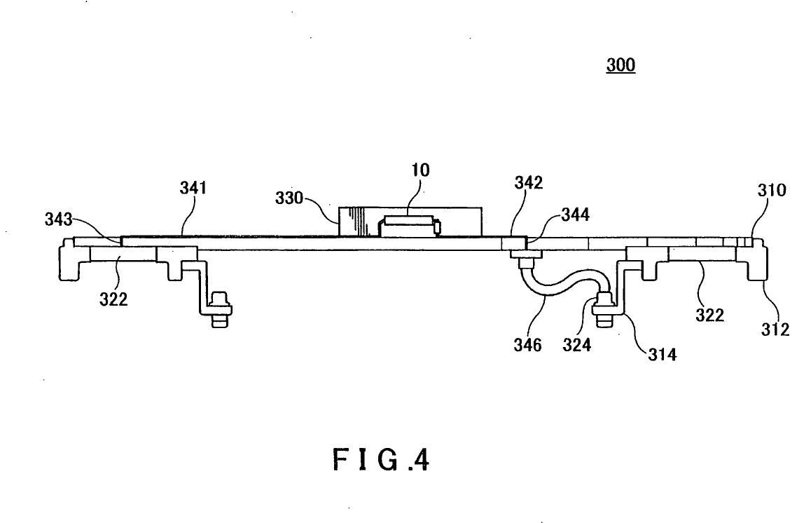

FIG. 4 is a vertical sectional view of the performance board 300 shown in FIG. 3. As shown in FIG. 4, an outer member 312 that includes a logic signal connector 322 is formed on a border portion of the bottom surface of the board main body 310. The outer member 312 reinforces the mechanical strength of the board main body 310 and easily sets the position of each unit. Furthermore, the RF signal connector 324 is suspended from the outer member 312 via a bracket 314.

Here, the logic signal connector 322 is disposed directly beneath the via 343 and is electrically connected to the test socket 330 via the via 343 and the signal line 341. Furthermore, the logic signal connector 322 has a shape that complements the logic signal receptacle 222 of the interface plate 200 and can be electrically connected by being inserted into the logic signal receptacle 222.

On the other hand, the RF signal connector 324 is electrically joined with the test socket 330 by the short coaxial cable 346 connected to a bottom end of the via 344. The RF signal connector 324 has a shape that complements the RF signal receptacle 224 of the interface plate 200 and can be electrically connected by being inserted into the RF signal receptacle 224.

As shown above and in FIG. 3 and FIG. 4, the performance board 300 includes a test socket 330 on which the device under test 10 can be mounted and is provided with the logic signal connector 322 and the RF signal connector 324 electrically corresponding to the each terminal of the test socket 330. The device under test 10 mounted on the test socket 330 can be connected to the outside via the logic signal connector 322 and the RF signal connector 324.

Furthermore, by fitting the logic signal connector 322 into the logic signal receptacle 222 and the RF signal connector 324 into the RF signal receptacle 224, both signal lines 341, 342 of the performance board 300 are electrically connected to the signal module 110 via the interface plate 200. In such a manner, testing can be performed by inputting and outputting the test signals between the signal module 110 and the device under test 10.

In the semiconductor testing device provided with the interface plate 200 as described above, the logic signal connector 322 and the RF signal connector 324 of the performance board 300 and the logic signal receptacle 222 and the RF signal receptacle 224 of the interface plate 200 are disposed in a manner to form a pair of each. Accordingly, the plurality of connectors can simultaneously be fit into the plurality of receptacles en bloc by pressing the performance board 300 onto the interface plate 200.

Furthermore, in the semiconductor testing device 20, even in a case where members having different fitting strokes are mixed into the plurality of connector pairs disposed between the interface plate 200 and the performance board 300, all of the connector pairs can be joined en bloc. This point is explained below.

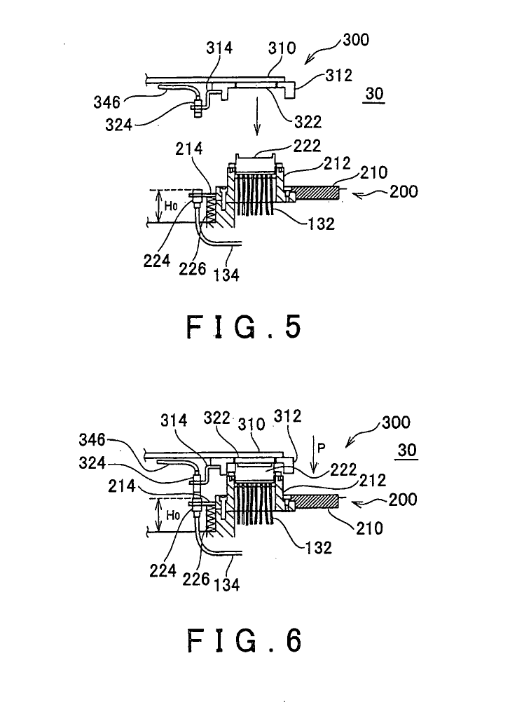

FIGS. 5 to 7 show a structure in which receptacles corresponding to connector pairs 30 having different fitting strokes are attached and an operation thereof. In FIGS. 5 to 7, the same reference numbers are given to structural elements common to FIGS. 1 to 4 and overlapping descriptions are omitted. Here, a case is shown in which the fitting stroke of the RF signal connector pair formed from the RF signal connector 324 and the RF signal receptacle 224 is shorter than the fitting stroke of the logic signal connector pair formed from the logic signal connector 322 and the logic signal receptacle 222.

FIG. 5 shows a condition in which the performance board 300 to be mounted is still separated from the interface plate 200. Here, the RF signal receptacle 224 is elastically suspended via the elastic member 226 and the bracket 214 in a manner such that the RF signal receptacle 224 can be displaced down from the plate body 210. However, because the RF signal receptacle 224 is open in this condition, the elastic member 226 is extended and a top end of the RF signal receptacle 224 is positioned at a height H₀ in relation to a bottom portion of the interface plate 200.

Next, as shown in FIG. 6, the performance board 300 is lowered, so that the logic signal connector 322 contacts the RF signal connector 324 and the logic signal receptacle 222 contacts the RF signal receptacle 224. Furthermore, when the performance board 300 is lowered, the connectors begin to fit into the receptacles in each connector pair until finally the RF signal connector pair having the short fitting stroke is fully fit in earlier. At this time, however, the logic signal connector pair is not yet fully fit in. Accordingly, a pushing pressure P is applied to further push the performance board 300, thereby completely fitting the logic signal connector pairs together.

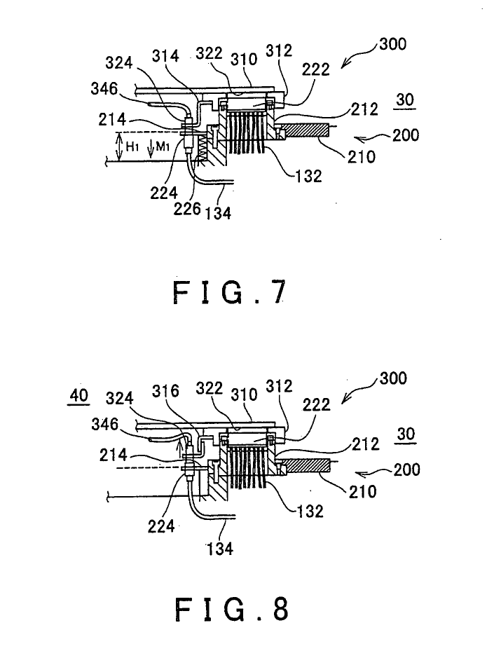

At this time, as shown in FIG. 7, because the elastically supported RF signal receptacle 224 falls to a height H₁ along with the already fully fit in RF signal connector 324 in the already fully fit in RF signal connector pair, falling of the logic signal connector 322 is not obstructed. In such a manner, the logic signal connector pair and the RF signal connector pair having different fitting strokes from each other can be completely fit in en bloc.

FIG. 8 shows a modification of the embodiment shown in FIGS. 5 to 7. In the connector pair 40 shown in the modification, the RF signal connector 324 in the performance board 300 is supported by an expanding/contracting bracket 316 that expands or contracts in a direction of the insertion or removal. The expanding/contracting bracket 316 is biased in a direction of expansion. FIG. 8 shows the same connection stage as FIG. 7, but in FIG. 8 the RF signal connector pair that is fully fit in earlier rises towards the elastically supported RF signal connector 324 because of the logic signal connector pair that is fully fit in later.

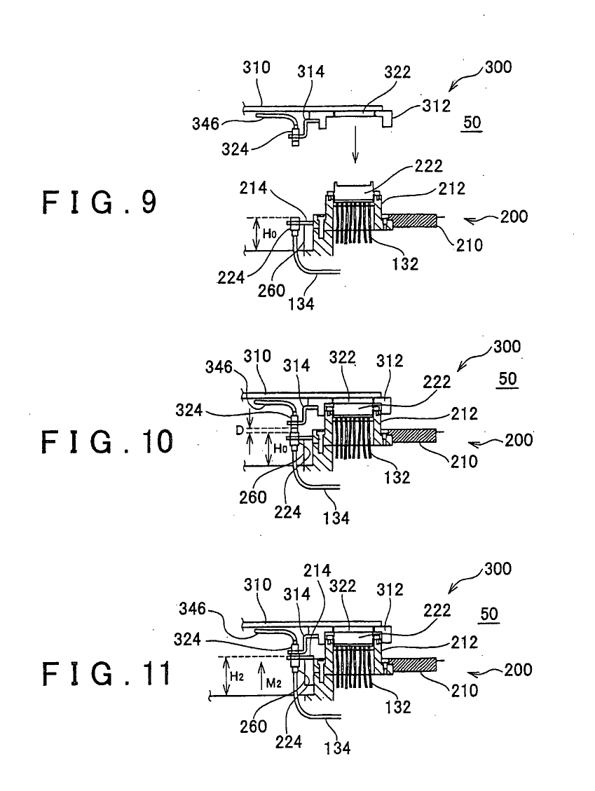

FIGS. 9 to 11 are views describing operations of connector pairs 50 according to other embodiments. In an embodiment described in FIGS. 9 to 11, a case is described in which the fitting stroke of the RF signal connector pair is longer than the fitting stroke of the logic signal connector pair. Furthermore, in the embodiment described in FIGS. 9 to 11, the RF signal receptacle 224 can be actively displaced. It should be noted that the operations are explained here while the structure in which the RF signal receptacle 224 can be actively displaced is described separately hereinafter.

First, FIG. 9 shows a condition in which the performance board 300 to be equipped is still separated from the interface plate 200. Here, the RF signal receptacle 224 is positioned at a lowest point within a range in which the RF signal receptacle 224 can move, and an upper end of the RF signal receptacle 224 is positioned at a height H₀ in relation to a bottom portion of the interface plate 200.

Next, as shown in FIG. 10, the performance board 300 is lowered, so that the logic signal connector 322 contacts the RF signal connector 324 and the logic signal receptacle 222 contacts the RF signal receptacle 224. Furthermore, when the performance board 300 is lowered, the logic signal connector pair having the short fitting stroke is fully fit in earlier. At this time, however, the RF signal connector pair is not yet fully fit in and a space D remains therebetween.

As shown in FIG. 11, the rise/fall receptacle holder 260 that supports the RF signal receptacle 224 is then raised in a direction of the arrow M₂ to the height H₂. Because the RF signal receptacle 224 is therefore also raised, the RF signal connector pair can be completely fit together. In the present embodiment in the manner described above, the RF signal receptacle 224 can be displaced at an arbitrary time. Accordingly, even where the connector pairs have the same fitting strokes, the pressing force required to attach the performance board can be decreased by staggering the timing of the insertion and removal.

In the description until now, as a matter of convenience, “connector pairs” are described in which a “connector” and a “receptacle” are combined, but the “connector” may also be a so-called plug (male), a jack (female), or a socket (female). Furthermore, in each case, the receptacle may have a male shape or a female shape as long as the connector can fit together with the receptacle.

Furthermore, separating the signals handled in the test apparatus into a logic signal and an RF signal is described above, but the test signals are not limited to such. In addition, each connector pair can be arbitrarily selected as long as each connector pair corresponds to each test signal and can be attached or detached by being inserted or removed in a specified direction. A push-on type of an OMPA-type, an OMPB-type, a BMA-type, an SMB-type, or an MCX-type is given as an example of the RF signal connector pair, but the RF signal connector pair is not limited to such.

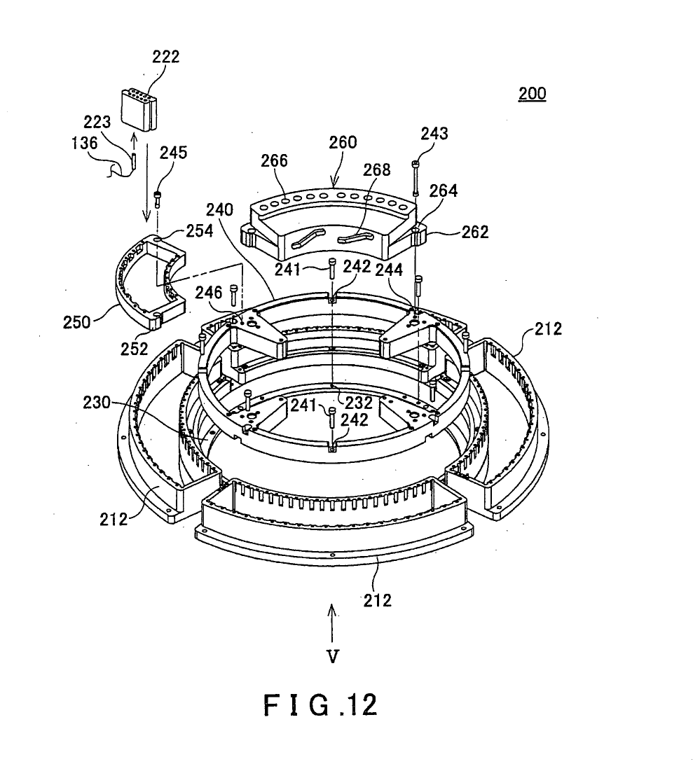

As in the embodiment shown in FIGS. 9 to 11, one embodiment of a structure in which the RF signal receptacle 224 can be actively displaced is shown below in FIG. 12. In FIG. 12, the same reference numbers are given to structural elements common to previous diagrams and overlapping descriptions are omitted.

FIG. 12 shows a support structure of a receptacle in the interface plate 200. It should be noted that a diagram of the plate body 210 is omitted.

In the semiconductor testing device 20, a multitude of receptacles are mounted on a single interface plate 200. By using receptacle holders that can each hold a plurality of receptacles and mounting a plurality of receptacle holders, mounting and replacement of the multitude of receptacles can be easily performed. In the embodiment shown in FIG. 12, three types of receptacle holders are disposed in a two-layered circle.

In other words, in the interface plate 200, four receptacle holders 212 having a shape of a quarter circle are arranged in a circle on an outer circumference side. The receptacle holders 212 contain on an inner side thereof a portion shaped in a manner to complement an outer shape of the logic signal receptacles 222 and can hold a plurality of logic signal receptacles 222. Furthermore, the receptacle holders 212 are directly secured to the plate body 210, not shown, of the interface plate 200. The logic signal receptacles 222 include a plurality of fitting holes, each of which contains therein a contact pin 136 connected to the logic signal module 112.

In addition, a circular support member 240 is disposed on an inner side of a circle created by the aforementioned receptacle holders 212 on the outer circumference. Receptacle holders 250 and rise/fall receptacle holders 260, each having a shape of a quarter circle, are alternately disposed on the support member 240 to form an overall circular shape.

In the present embodiment, the receptacle holders 250 on the inner circumference also contain on an inner side thereof a portion shaped to complement the outer shape of the logic signal receptacles 222 and can hold a plurality of logic signal receptacles 222. On the other hand, the rise/fall receptacle holders 260 include a plurality of holding sections 266 that can contain the RF signal receptacles 224. In such a manner, each receptacle holder 250 and rise/fall receptacle holder 260 holds connector pairs having the same fitting stroke.

Here, the support member 240 includes a plurality of through holes 242 thereon, so that the support member 240 can be secured to the plate body 210, not shown, by screws 241 inserted therein. Furthermore, the receptacle holders 250 are secured to the threaded holes 246 of the support member 240 by screws 245 inserted into through holes 254 formed at ribs 252 at both ends of the receptacle holders 250. Accordingly, the aforementioned members are not displaced in relation to the plate body 210.

The rise/fall receptacle holders 260 are attached to the support member 240 by guide pins 243 inserted into through holes 264 formed in ribs 262 at both ends of the rise/fall receptacle holders 260. It should be noted that the guide pins 243 have grooves cut into an area at a bottom end thereof, and a portion of the guide pins 243 inserted into the through holes 264 has a smooth cylindrical shape. Furthermore, a length of the cylindrical portion is sufficiently larger than a width of the ribs 262 of the rise/fall receptacle holders 260. In addition, an inner circumference of the through holes 264 is slightly larger than the guide pins 243. Accordingly, the rise/fall receptacle holders 260 can be guided by the guide pins 243 to be displaced in a rising and falling direction.

The rise/fall receptacle holders 260 include diagonal elongated holes 268 on a surface of the inner side thereof. The rise/fall receptacle holders 260 can be actively displaced by horizontally displacing the members contacting the elongated holes 268 on the inner side.

Horizontal portions are formed at both ends of the elongated holes 268. Therefore, horizontal stress is not generated, even where a load acts in a vertical direction on the rise/fall receptacle holders 260 in a highest or lowest position.

Furthermore, in a condition where the performance board 300 is attached to the interface plate 200, the test socket 330 on which the device under test 10 is mounted is positioned at a substantial center of the circular receptacle holders 212, 250, 260. Accordingly, the length of each signal path is the same in the test signal paths leading from the device under test 10 to the interface plate 200.

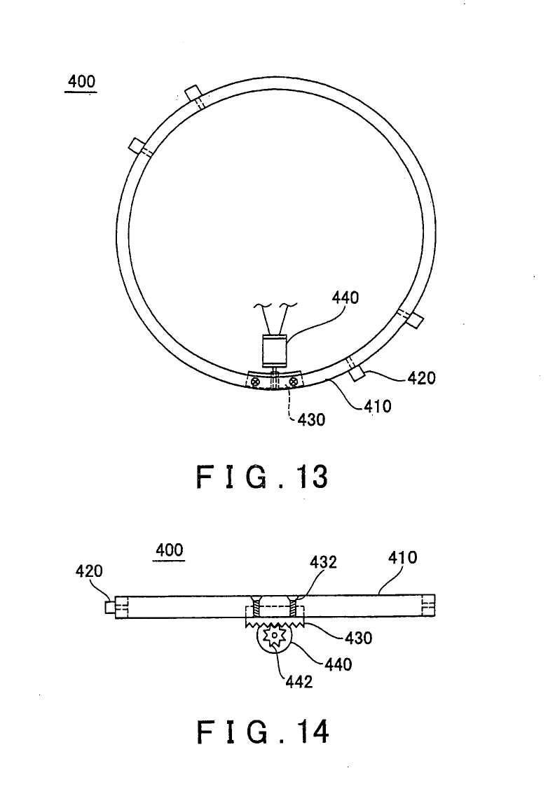

FIG. 13 is a plan view showing a single driving section 400 that drives displacement of the rise/fall receptacle holder 260 via the elongated holes 268 in the interface plate 200 shown in FIG. 12 (a drawing of the driving section 400 is omitted form FIG. 12). As shown in FIG. 13, the driving section 400 includes a plurality of driving pins 420 projecting outward and attached to an outer surface of a ring 410. As described hereinafter, tips of the driving pins 420 are disposed in a manner to enter into the elongated holes 268 of the rise/fall receptacle holders 260.

FIG. 14 is a view of the driving section 400 shown in FIG. 13 as seen from the side. As shown in FIG. 14, a rack 430 is secured by a screw 432 to a bottom surface of the ring 410. The rack 430 interlocks with a pinion gear 442 that is rotationally driven by a motor 440. Accordingly, the ring 410 can be rotated to horizontally displace the driving pin 420 by an operation of the motor 440.

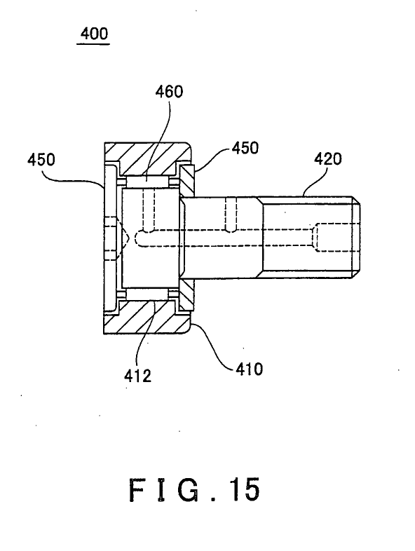

FIG. 15 is a cross-sectional view showing a structure in which the driving pin 420 is installed in the driving section 400. As shown in FIG. 15, an end portion of the driving pin 420 is inserted into a housing 412 formed on the ring 410 via a roller bearing 460. The end portion of the driving pin 420 and the roller bearing 460 are sealed by a bearing bar 450, so as not to fall away from the ring 410. Because the driving pin 420 can rotate smoothly through such a structure, a driving force in a vertical direction in relation to the elongated holes 268 can be effectively transmitted.

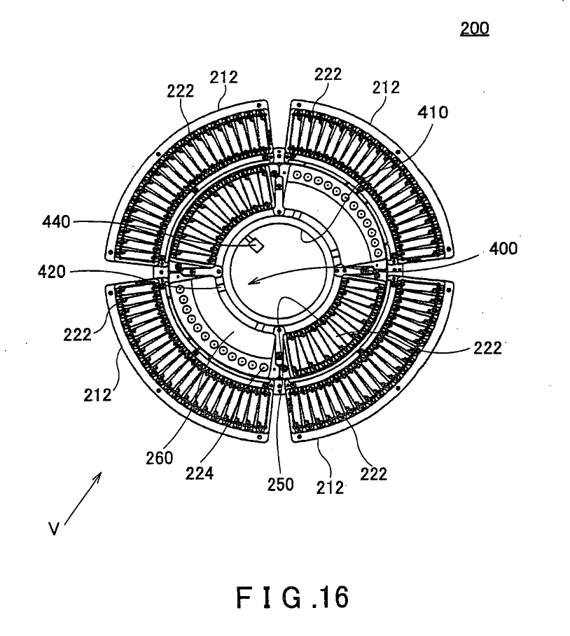

FIG. 16 is a plan view showing a condition in which the driving section 400 shown in FIGS. 13 to 15 is attached to the interface plate 200 shown in FIG. 12. To clarify the positional relationship with FIG. 12, an arrow V indicating the view of FIG. 12 is included in the diagram.

As shown in FIG. 16, a multitude of logic signal receptacles 222 is loaded into the receptacle holders 212, 250. Furthermore, a plurality of RF signal receptacles 224 is held by the rise/fall receptacle holders 260.

The driving section 400 is disposed at an inner side of the circle formed by the receptacle holders 250 and the rise/fall receptacle holders 260. At this time, the driving pins 420 are inserted into the elongated holes 268 of the rise/fall receptacle holders 260. Furthermore, the motor 440 is secured to the plate body 210 of the interface plate 200 by a section, not shown.

In the interface plate 200 formed as described above, by causing the motor 440 to drive and rotate the ring 410, the driving pins 420 contact an internal surface of the elongated holes 268. Furthermore, when the ring 410 rotates, the rise/fall receptacle holders 260 are raised or lowered in accordance with the slant of the elongated holes 268. Because both the raising and lowering are active operations, the mechanical resistance caused by the insertion or removal of the RF signal receptacles 224 held by the rise/fall receptacle holders 260 is overcome and the RF signal connectors 324 can be inserted or removed.

In the aforementioned embodiments, a case is described in which rise/fall receptacle holders 260 having the same shape are displaced by a single ring 410. However, a variety of connector pairs can be inserted or removed with a single driving section 400 by mixing in rise/fall receptacle holders 260 having elongated holes 268 with different slants, for example. Furthermore, a portion of the connector pairs can be inserted or removed at a different timing by using a plurality of driving sections 400 that drive independently.

In the aforementioned embodiments, a driving section 400 having driving pins 420 attached at locations corresponding to a disposition of the rise/fall receptacle holders 260 is used, but the function of the driving pins 420 can be negated by forming large holes having an inner surface that does not contact the driving pins 420 on the receptacle holders 250 that do not rise or fall.

In the aforementioned embodiments, a case is described in which the rise/fall receptacle holders 260 are displaced, but a structure in which the receptacles themselves are displaced may also be used. Furthermore, a type, a number, a grouping, a disposition, or the like of the receptacles and the receptacle holders are not limited to those described in the above embodiments.

While aspects of the present invention have been described through embodiments, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

As made clear from the above description, through embodiments of the present invention, an interface plate is provided that can simultaneously connect all connector pairs en bloc, even in a case where members having different fitting strokes are included in the connector pairs that join between the interface plate and a performance board. Furthermore, as described hereinafter, a pressing force for attaching the performance board can be decreased by using the aforementioned function and decreasing the number of connector pairs that are simultaneously inserted or removed.

What is claimed is:

1. A semiconductor testing device, comprising:
a test head that includes a signal module that generates and processes test signals input to and then output from a device under test;
an interface plate that is attached to the test head and includes a plate body and a plurality of receptacles electrically connected to the signal module and disposed on the plate body; and
a performance board that includes on one surface connectors fit into and electrically connected to the receptacles and on another surface a test socket that is electrically joined with the connectors and on which the device under test can be mounted and is attached to the interface plate by fitting the connectors into the receptacles, wherein the plurality of receptacles or the plurality of connectors include rise/fall receptacles or rise/fall connectors that are displaced in relation to the plate body in a direction in which the connectors are inserted into or removed from the receptacles.

2. The semiconductor testing device according to claim 1, wherein the plurality of connectors and receptacles is disposed in a circle that surrounds the device under test attached to the test socket.

3. The semiconductor testing device according to claim 1, wherein the plurality of connectors and receptacles is disposed in a plurality of circles, each circle having a common center, that surrounds the device under test attached to the test socket.

4. The semiconductor testing device according to claim 1, wherein the rise/fall receptacles or the rise/fall connectors are elastically supported from the plate body and are displaced together with the inserted connectors in a direction in which the connectors are inserted or removed.

5. The semiconductor testing device according to claim 1, wherein the receptacles are supported by the plate body via receptacle holders that have a portion with a shape complementing the receptacles and hold the plurality of receptacles.

6. The semiconductor testing device according to claim 5, wherein the receptacle holders include a rise/fall receptacle holder that holds the rise/fall receptacles, and the rise/fall receptacle holder displaces in relation to the plate body in a direction in which the connectors are inserted into or removed from the receptacles by displacing in relation to the plate body in a direction in which the connectors are inserted into or removed from the receptacles.

7. The semiconductor testing device according to claim 5, wherein the receptacle holders are disposed in a circle that surrounds the device under test attached to the test socket.

8. The semiconductor testing device according to claim 5, wherein the receptacle holders are disposed in a plurality of circles, each circle having a common center, that surrounds the device under test attached to the test socket.

9. The semiconductor testing device according to claim 7, wherein each receptacle holder holds the receptacles having fitting strokes equal to one another.

10. The semiconductor testing device according to claim 6, further comprising:
a guiding section that guides the displacement of the rise/fall receptacle holder in a direction in which the connectors are inserted into or removed from the receptacles;
a slanted surface formed on the rise/fall receptacle holder that slants in relation to a front surface of the plate body; and
a driving section that displaces the rise/fall receptacle holder by contacting the slanted surface and displacing the rise/fall receptacle holder horizontally.

11. The semiconductor testing device according to claim 1, wherein the fitting strokes of the rise/fall receptacles and the corresponding connectors are longer than the fitting strokes of other receptacles and corresponding connectors, and during a procedure in which the connectors are fit into the receptacles, the rise/fall receptacles are displaced toward the connectors after the other connectors are fit into the other receptacles.

12. The semiconductor testing device according to claim 1, wherein the fitting strokes of the rise/fall receptacles and the corresponding connectors are shorter than the fitting strokes of other receptacles and corresponding connectors, and during a procedure in which the connectors are fit into the receptacles, the rise/fall receptacles and the connectors are displaced until the other connectors are fit into the other receptacles after the connectors are fit into the rise/fall receptacles.

13. The semiconductor testing device according to claim 1, wherein the receptacles are multi-receptacles that have a plurality of terminals causing electrical coupling independent of one another.

14. The semiconductor testing device according to claim 1, wherein the receptacles are coaxial receptacles that have a core line and a conductive shield surrounding the core line.

15. An interface plate on which is loaded a performance board that is provided with a plate body attached to a test head of a semiconductor testing device and a plurality of receptacles disposed on the plate body and electrically connected to a signal module that generates test signals for testing the device under test and includes on one surface thereof connectors that are fit into and electrically connected to the receptacles, wherein the plurality of receptacles includes rise/fall receptacles that are displaced in relation to the plate body in a direction in which the connectors are inserted into or removed from the receptacles.

16. A performance board, comprising:
a test socket on which a device under test can be mounted on a test head of a semiconductor testing device;
a board main body on which the test socket is loaded on one surface thereof, and
a plurality of connectors, attached to another surface of the board main body, that fits into receptacles that are electrically connected to a signal module that generates test signals for testing the device under test, wherein the plurality of connectors includes rise/fall connectors that are displaced in relation to the board main body in a direction in which the connectors are inserted into or removed from the receptacles.
